(19) United States
(12) Patent Application Publication
(10) Pub. No.: US 2008/0283936 A1
(43) Pub. Date: Nov. 20, 2008

(54) SILICON GERMANIUM FLOW WITH RAISED SOURCE/DRAIN REGIONS IN THE NMOS

(75) Inventors: Seetharaman Sridhar, Richardson, TX (US); Majid Mansoori, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/750,703

(22) Filed: May 18, 2007

(51) Int. Cl. H01L 27/092; H01L 21/8238

(52) U.S. Cl. 257/401; 438/233; 257/E27.064; 257/E21.634; 257/E21.641

(57) ABSTRACT

Provided is a method for manufacturing a semiconductor device that includes a substrate having a PMOS device region and NMOS device region. A first gate structure including a first hardmask and a second gate structure including a second hardmask are formed in the region and region, respectively. Epitaxial SiGe regions are created in the substrate proximate the first gate structure, the first hardmask protecting the first gate structure from the SiGe. First source/drain regions are formed proximate the first gate structure, at least a portion of each of the first source/drain regions located within one of the SiGe regions. Additionally, a raised portion is grown above the substrate proximate the second gate structure, the portion forming at least a part of second source/drain regions located on opposing sides of the second gate structure. Additionally, the first and second hardmasks protect the first and second gate structures from the growing.

### TECHNICAL FIELD OF THE INVENTION

The disclosure is directed, in general, to a semiconductor device and, more specifically, to a silicon germanium flow with raised source/drain regions in the NMOS.

### BACKGROUND OF THE INVENTION

There exists a continuing need to improve semiconductor device performance and further scale semiconductor devices. A characteristic that limits scalability and device performance is electron and/or hole mobility (e.g., also referred to as channel mobility) throughout the channel region of transistors. As devices continue to shrink in size, the channel region also continues to shrink in size, which can limit channel mobility.

One technique that may improve scaling limits and device performance is to introduce strain into the channel region, which can improve electron and/or hole mobility. Different types of strain, including expansive strain, uniaxial tensile strain, and compressive strain, have been introduced into channel regions of various types of transistors in order to determine their effect on electron and/or hole mobility. For some devices, certain types of strain improve mobility whereas other types degrade mobility.

One process known and used to create strain within the channel region is to form a layer of strain inducing material over the gate structure. The strain inducing material may then be subjected to an annealing process to create the strain within the channel region. Unfortunately, it has been observed that the introduction of just one kind of strain into the channel region using such a strain-inducing layer is insufficient to support some of the next generation devices.

Accordingly, what is needed in the art is an improved method for manufacturing a semiconductor device that provides improved channel mobility and/or lowered source/drain resistance.

### SUMMARY OF THE INVENTION

To address the above-discussed deficiencies of the prior art, the disclosure provides a semiconductor device and method of manufacture therefore. The semiconductor device, in one embodiment, includes a P-type metal oxide semiconductor (PMOS) device region located over a substrate and an N-type metal oxide semiconductor (NMOS) device region located over the substrate. The PMOS device region, in this embodiment, includes a first gate structure located over the substrate, the first gate structure including a first gate dielectric and a first gate electrode. The first gate structure further includes recessed epitaxial silicon germanium regions located in the substrate on opposing sides of the first gate structure, and first source/drain regions located on opposing sides of the first gate structure. In this embodiment at least a portion of each of the first source/drain regions is located within one of the recessed epitaxial silicon germanium regions. The NMOS device region, in this embodiment, includes a second gate structure located over the substrate, the second gate structure including a second gate dielectric and a second gate electrode. The NMOS device region further includes second source/drain regions located on opposing sides of the second gate structure, wherein each of the second source/drain regions includes a raised portion located above the substrate and does not comprise epitaxial silicon germanium.

Additionally provided is a method for manufacturing a semiconductor device. This method, in one embodiment, includes providing a substrate having a P-type metal oxide semiconductor (PMOS) device region and N-type metal oxide semiconductor (NMOS) device region, and forming a first gate structure including a first hardmask over the substrate in the PMOS device region and a second gate structure including a second hardmask over the substrate in the NMOS device region. This method further includes creating recessed epitaxial silicon germanium regions in the substrate on opposing sides of the first gate structure, the first hardmask protecting the first gate structure from the creating, and forming first source/drain regions on opposing sides of the first gate structure, wherein at least a portion of each of the first source/drain regions is located within one of the recessed epitaxial silicon germanium regions. Additionally, a raised portion is grown above the substrate on opposing sides of the second gate structure, the raised portion forming at least a part of second source/drain regions located on opposing sides of the second gate structure, and further wherein the first and second hardmasks protect the first and second gate structures from the growing.

Also provided is a method for manufacturing a semiconductor device. The method, without limitation, may include: 1) forming a substrate having a P-type metal oxide semiconductor (PMOS) device region and N-type metal oxide semiconductor (NMOS) device region, 2) forming a first gate structure over the substrate in the PMOS device region and a second gate structure over the substrate in the NMOS device region, 3) forming recessed epitaxial silicon germanium regions in the substrate on opposing sides of the first gate structure, 4) forming first source/drain regions on opposing sides of the first gate structure, wherein at least a portion of each of the first source/drain regions is located within one of the recessed epitaxial silicon germanium regions, and 5) forming second source/drain regions on opposing sides of the second gate structure, wherein each of the second source/drain regions includes a raised portion located above the substrate and does not comprise epitaxial silicon germanium.

### BRIEF DESCRIPTION OF THE DRAWINGS

For a more complete understanding of the disclosure, reference is now made to the following descriptions taken in conjunction with the accompanying drawings, in which:

FIG. 1 illustrates a semiconductor device manufactured in accordance with an example embodiment;

FIGS. 2-11 illustrate detailed steps of one example embodiment for manufacturing a semiconductor device in accordance with this disclosure; and

FIG. 12 illustrates an integrated circuit (IC) having been manufactured using one embodiment of the disclosure.

### DETAILED DESCRIPTION

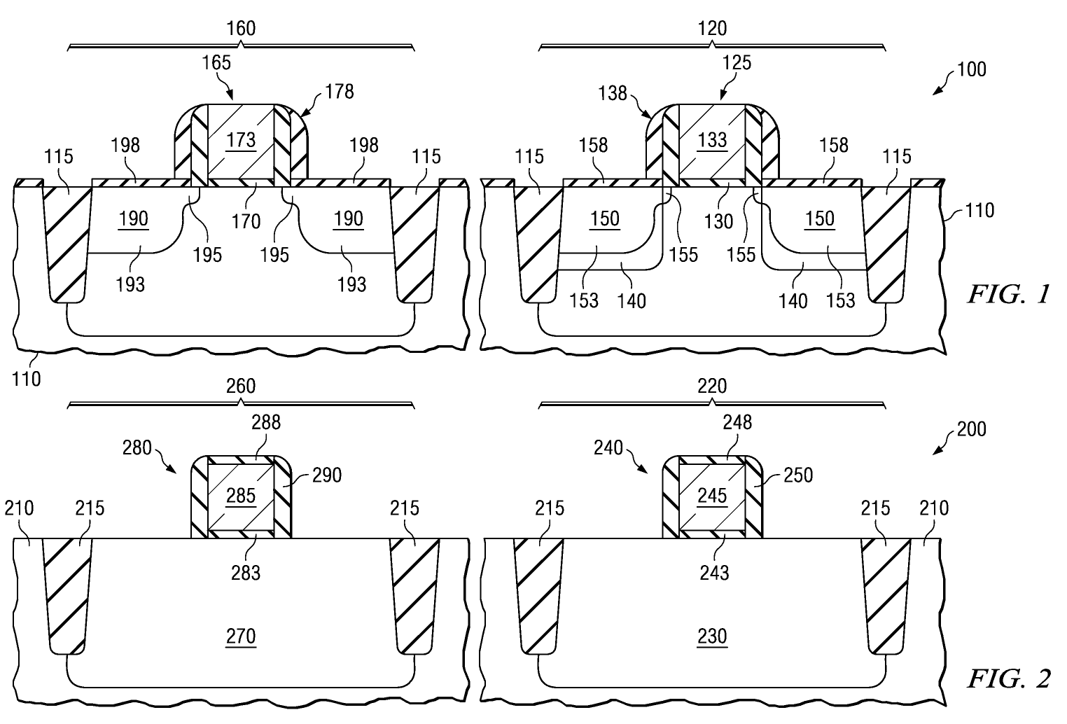

FIG. 1 illustrates a semiconductor device 100 manufactured in accordance with an example embodiment. The semiconductor device 100 includes a substrate 110. Located within the substrate 110 are isolation regions 115. The isolation regions 115 of FIG. 1 are depicted as shallow trench isolation (STI) regions. Nevertheless, any other type isolation region may be used, for example field oxide regions (also known as “LOCOS” regions), implanted isolation regions, etc.

The substrate 110 of FIG. 1 further includes a P-type metal oxide semiconductor (PMOS) device region 120 and an N-type metal oxide semiconductor (NMOS) device region 160. In the example embodiment of FIG. 1, the isolation regions 115 help define the boundaries of the PMOS device region 120 and the NMOS device region 160. Nevertheless, other features or structures could be used to define such boundaries.

The PMOS device region 120 of FIG. 1 includes a first gate structure 125 located over the substrate 110. The first gate structure 125, in this embodiment, includes a first gate dielectric 130, a first gate electrode 133 and gate sidewall spacers 138. The first gate dielectric 130, first gate electrode 133, and gate sidewall spacers 138 may comprise many different materials, conventional and not, and remain within the scope of this disclosure.

The PMOS device region 120 of FIG. 1 further includes recessed epitaxial silicon germanium (“SiGe”) regions 140. The SiGe regions 140, in the example embodiment, are located in the substrate 110 on opposing sides of the first gate structure 125. Moreover, the SiGe regions 140 are offset from a sidewall of the gate structure 125 using at least a portion of the gate sidewall spacers 138. While the SiGe regions 140 appear to have substantially vertical sidewalls, certain other embodiments exist wherein the SiGe regions 140 have sidewalls that angle under the gate structure 125.

The SiGe regions 140 are employed within the PMOS device region 120 to improve transistor performance by increasing the mobility of the carriers in the channel thereof. It is believed that the improvement is a result of the lattice mismatch that induces mechanical stress or strain across the channel regions. Specifically, a compressive-strained channel typically provides the hole mobility enhancement that is beneficial for the PMOS device region 120.

The PMOS device region 120 further includes first source/drain regions 150 located on opposing sides of the first gate structure 125. Each of the first source/drain regions 150, or at least a portion thereof, is located within one of the SiGe regions 140. The first source/drain regions 150, in the embodiment of FIG. 1, include first source/drain implants 153 and first extension implants 155. The first source/drain regions 150 further include raised portions 158. As will be more evident below, the raised portions 158 may comprise the same material as the raised portions 198 in the NMOS device region 160. Additionally, the raised portions 158, in certain embodiments, will not comprise epitaxial silicon germanium.

The substrate 110 further includes the NMOS device region 160. The NMOS device region 160 includes a second gate structure 165 located over the substrate 110. The second gate structure 165, in this embodiment, includes a second gate dielectric 170, a second gate electrode 173 and gate sidewall spacers 178. Similar to above, the second gate dielectric 170, second gate electrode 173, and gate sidewall spacers 178 may comprise many different materials, conventional and not.

The NMOS device region 160 further includes second source/drain regions 190 located on opposing sides of the second gate structure 165. Each of the second source/drain regions 190 include a raised portion 198 located above the substrate 110. For example, the raised portions 198 are located above a top surface of the substrate 110. The raised portions 198, in one embodiment, do not comprise epitaxial silicon germanium. Nevertheless, the raised portions 198 may comprise epitaxial silicon or silicon carbon, among others, and remain within the purview of this disclosure. Likewise, an interface may be located at a junction where the substrate 110 and raised portions 198 touch one another.

Each of the second source/drain regions 190, at least in the example embodiment of FIG. 1, further includes second source/drain implants 193 and second extension implants 195. Depending on the process for forming the semiconductor device 100, at least a portion of the second source/drain implants 193 may be located in the raised portions 198. In an alternative embodiment, at least a portion of the second extension implants 195 are also located within the raised portions 198.

The semiconductor device 100 of FIG. 1 benefits significantly by collectively using the recessed epitaxial silicon germanium regions 140 in the PMOS device region 120 and the raised source/drain portions 198 in the NMOS device region 160. For example, the PMOS device region 120 has improved channel mobility whereas the NMOS device region 160 has improved series resistance. Heretofore the present disclosure, these two features were not used in a same semiconductor device comprising a PMOS device region and an NMOS device region. It is believed that this is in part due to the extreme expense associated with protecting the gate electrodes from the growth of the raised source/drain portions 198. Nevertheless, because the gate electrodes were already protected during the formation of the recessed epitaxial silicon germanium regions 140, the raised source/drain portions 198 could be inexpensively added.

FIGS. 2-11 illustrate detailed steps of one example embodiment for manufacturing a semiconductor device in accordance with this disclosure. FIG. 2 illustrates a semiconductor device 200 at an initial stage of manufacture. The device 200 includes a substrate 210. The substrate 210 may, in one embodiment, be any layer located in the device 200, including a wafer itself or a layer located above the wafer (e.g., epitaxial layer). In the embodiment illustrated in FIG. 2, the substrate 210 is a P-type substrate; however, one skilled in the art understands that the substrate 210 could be an N-type substrate without departing from the disclosure. In such an embodiment, each of the dopant types described throughout the remainder of this document might be reversed. For clarity, no further reference to this opposite scheme will be discussed.

Located within the substrate 210 in FIG. 2 are isolation regions 215. The isolation regions 215 are configured to isolate various device features of the device 200 from one another. In the illustrative embodiment of FIG. 2, the isolation regions 215 are shallow trench isolation structures. Nevertheless, the isolation regions 215 may comprise various other types of isolation structures. As those skilled in the art understand the various steps used to form the isolation regions 215, whether they are shallow trench isolation structures, LOCOS isolation structures, or another structure, no further detail will be given.

The substrate 210 of FIG. 2 includes two device regions. For example, the substrate 210 includes a PMOS device region 220 and an NMOS device region 260. Other embodiments may exist wherein the substrate 210 includes multiple PMOS device regions 220 and/or multiple NMOS device regions 260.

Located within the substrate 210 in the PMOS device region 220 is a well region 230. The well region 230, in the embodiment of FIG. 2, contains an N-type dopant. For example, the well region 230 would likely be doped with an N-type dopant dose ranging from about 1E13 atoms/cm² to about 1E14 atoms/cm² and at an energy ranging from about 100 keV to about 500 keV. This may result in the well region 230 having a peak dopant concentration ranging from about 5E17 atoms/cm³ to about 1E19 atoms/cm³.

Located over the well region 230 is a first gate structure 240. The gate structure 240 includes a first gate dielectric 243, a first gate electrode 245, a gate hardmask 248, and gate sidewall spacers 250. The gate dielectric 243 may comprise a number of different materials and stay within the scope of the disclosure. For example, the gate dielectric 243 may comprise silicon dioxide, or in an alternative embodiment comprise a high dielectric constant (K) material. In the illustrative embodiment of FIG. 2, however, the gate dielectric 243 is a silicon dioxide layer having a thickness ranging from about 0.5 nm to about 5 nm.

Any one of a plurality of manufacturing techniques could be used to form the gate dielectric 243. For example, the gate dielectric 243 may be either grown or deposited. Additionally, the growth or deposition steps may require a significant number of different temperatures, pressures, gasses, flow rates, etc.

While the embodiment of FIG. 2 discloses that the gate electrode 245 comprises standard polysilicon, other embodiments exist where the gate electrode 245, or at least a portion thereof, comprises amorphous polysilicon material, a metal material, or fully silicided metal material. The amorphous polysilicon embodiment may be particularly useful when a substantially planar upper surface of the gate electrode 245 is desired.

The deposition conditions for the gate electrode 245 may vary. However, if the gate electrode 245 were to comprise standard polysilicon, such as the instance in FIG. 2, the gate electrode 245 could be deposited using a pressure ranging from about 100 Torr to about 300 Torr, a temperature ranging from about 620° C. to about 700° C., and a SiH₄ or Si₂H₆ gas flow ranging from about 50 sccm to about 150 sccm. If, the gate electrode 245 were to comprise a different material, other suitable deposition conditions might be used. The gate electrode 245, in various embodiments, may have a thickness ranging from about 50 nm to about 150 nm, among others.

The gate hardmask 248 may comprise various different materials. In one embodiment, however, the gate hardmask 248 comprises silicon carbide. In alternative embodiments, the gate hardmask 245 comprise silicon nitride or silicon oxynitride, among others. Those skilled in the art understand the processes, whether conventional or not, that might be used to form the gate hardmask 248.

The gate sidewall spacers 250 of the first gate structure 240 may comprise many different materials. In the particular embodiment of FIG. 2 the gate sidewall spacers 250 comprise silicon nitride. Nevertheless, in other embodiments the gate sidewall spacers 250 may comprise silicon dioxide, silicon carbide or silicon oxynitride, without limitation. In certain embodiments, it is important that the gate sidewall spacers 250 and the gate hardmask 248 comprise different materials. In these embodiments, the difference in material allows one feature to be selectively removed without significant removal of the other feature.

Those skilled in the art understand the processes that might be used to form the gate sidewall spacers 250. For example, in one embodiment a conformal layer of gate sidewall material is deposited on the gate structure 240 and the substrate 210 using a chemical vapor deposition (CVD) process to an appropriate thickness. Thereafter, the conformal layer of gate sidewall material is subjected to an anisotropic etch, thus resulting in the gate sidewall spacers 250.

Located within the substrate 210 in the NMOS device region 260 is a well region 270. The well region 270, as a result of being located within the NMOS device region 260, would generally contain a P-type dopant. For example, the well region 270 would likely be doped with a P-type dopant dose ranging from about 1E13 atoms/cm² to about 1E14 atoms/cm² and at an energy ranging from about 100 keV to about 500 keV. This may result in the well region 270 having a peak dopant concentration ranging from about 5E17 atoms/cm³ to about 1E19 atoms/cm³. Those skilled in the art understand that in certain circumstances where the P-type substrate 210 dopant concentration is high enough, the well region 270 may be excluded.

Located over the well region 270 is a second gate structure 280. The gate structure 280 includes a second gate dielectric 283, a second gate electrode 285, a gate hardmask 288, and gate sidewall spacers 290. Each of the second gate dielectric 283, second gate electrode 285, gate hardmask 288, and gate sidewall spacers 290 may comprise similar materials and be formed using similar processes as each of the first gate dielectric 243, first gate electrode 245, gate hardmask 248, and gate sidewall spacers 250, respectively. In many instances, the related features are formed using the same processing steps, and only thereafter patterned resulting in the first gate structure 240 and the second gate structure 280.

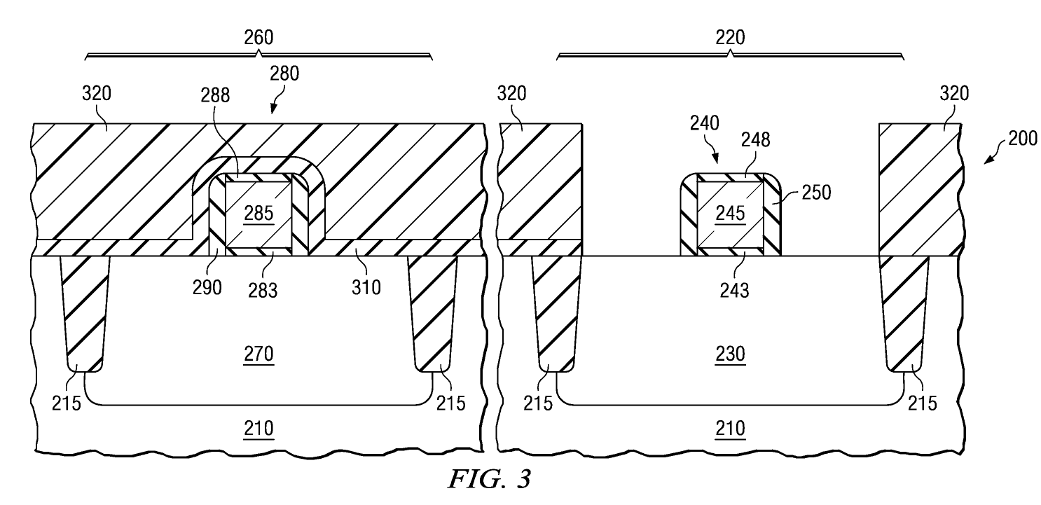

FIG. 3 illustrates is the device 200 of FIG. 2 after patterning a masking layer 310 and resist layer 320 to expose at least a portion of the PMOS device region 220. Those skilled in the art understand the process of patterning the masking layer 310 and the resist layer 320. The process would generally begin by depositing a conformal layer of masking material over the substrate 210. The layer of masking material, in this embodiment, may comprise an insulative material, such as SiO₂, SiN, or a combination thereof. In one specific embodiment, however, the layer of masking material comprises a first layer of oxide (SiO₂) and a layer of nitride (SiN) However, a second layer of oxide may be used over the nitride layer. As an example, the first oxide layer may have a thickness ranging from about 1.5 nm to about 10 nm, the layer of nitride may have a thickness ranging from about 2.0 nm to about 15 nm, and the optional second layer of oxide may have thickness ranging from about 1.0 nm to about 10 nm. Any suitable Chemical Vapor Deposition (“CVD”) or furnace-based machine may be used to form the layer of masking material.

Thereafter, a radiation sensitive resist coating (e.g., a conformal layer of resist) would be formed over the conformal layer of masking material. The radiation sensitive resist coating would then be patterned by selectively exposing the resist through a mask. In turn, the exposed areas of the coating become either more or less soluble than the unexposed areas, depending on the type of resist. A solvent developer would then be used to remove the less soluble areas leaving the patterned resist layer 320. The patterned resist layer 320, and an appropriate etch, could then be used to pattern the masking layer 310, thus exposing the substrate 210 in at least a portion of the PMOS device region 220 of the device 200.

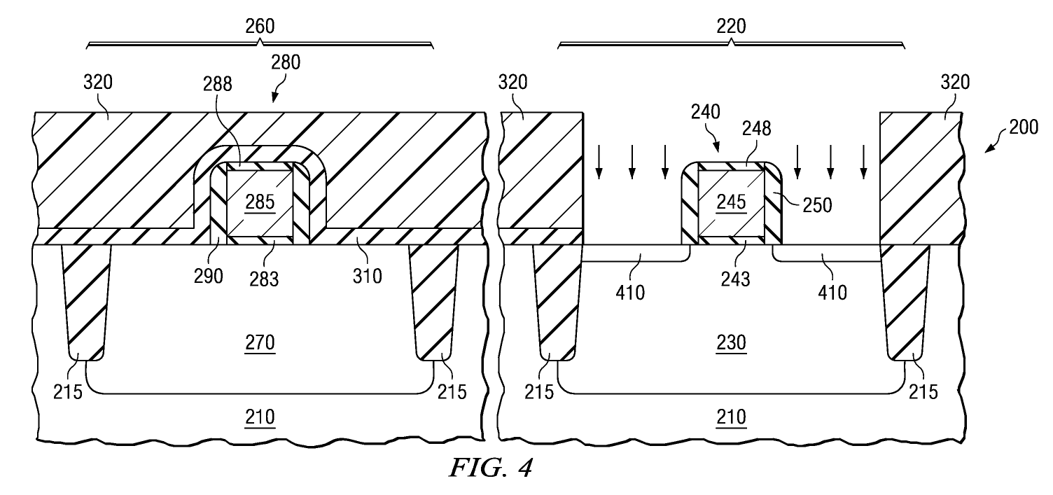

FIG. 4 illustrates the device 200 of FIG. 3 after forming extension implants 410 within the substrate 210 in the PMOS device region 220. In the given embodiment, the patterned masking layer 310, patterned resist layer 320 and the first gate structure 240 help position the extension implants 410 within the substrate. The extension implants 410 may be conventionally formed and generally have a peak dopant concentration ranging from about 1E19 atoms/cm³ to about 2E20 atoms/cm³. As is standard in the industry, the implants 410 should have a dopant type opposite to that of the well region 230 they are located within. Accordingly, the implants 410 of FIG. 4 are doped with a P-type dopant.

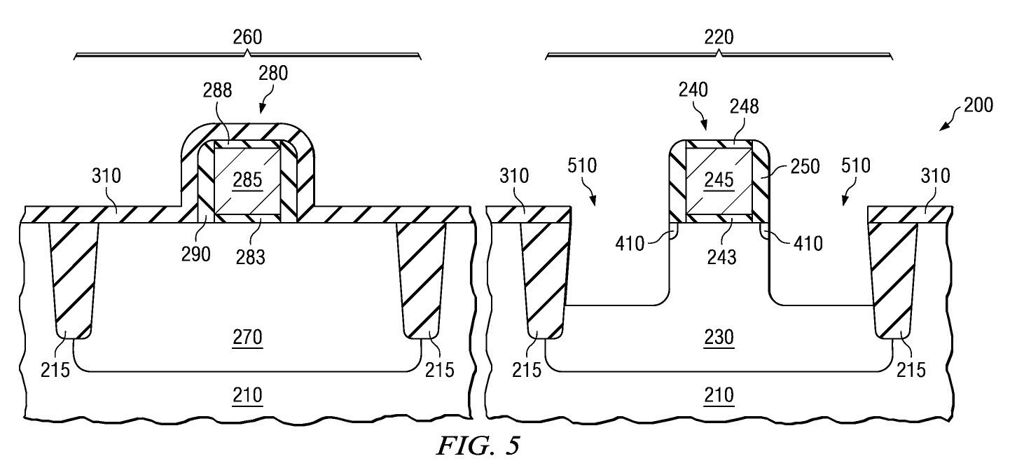

FIG. 5 illustrates the device 200 of FIG. 4 after removing the patterned resist layer 320 and using the patterned masking layer 310 to form recesses 510 within the substrate 210. Those skilled in the art understand the steps required to remove the patterned resist layer 320. Accordingly, no further detail need be given.

The process of etching the recesses 510 may be conventional or not. In one embodiment, a standard silicon etch is used. For example, the etch may be a “box silicon etch”, as shown in FIG. 5. In this embodiment, an anisotropic etch would be used. Because of the anisotropic nature of this etch, the recesses 510 formed by the etch shouldn't cause an excessive removal of the extension implants 410. Alternatively, an isotropic etch or combination of isotropic and anisotropic etch could be used. In this embodiment, the isotropic component will generally undercut portions of the silicon, thereby creating recesses 510 that encroach closer to the channel region and remove more material in the extension implants 410 (thus creating a corresponding change in the dosing level of those extension regions).

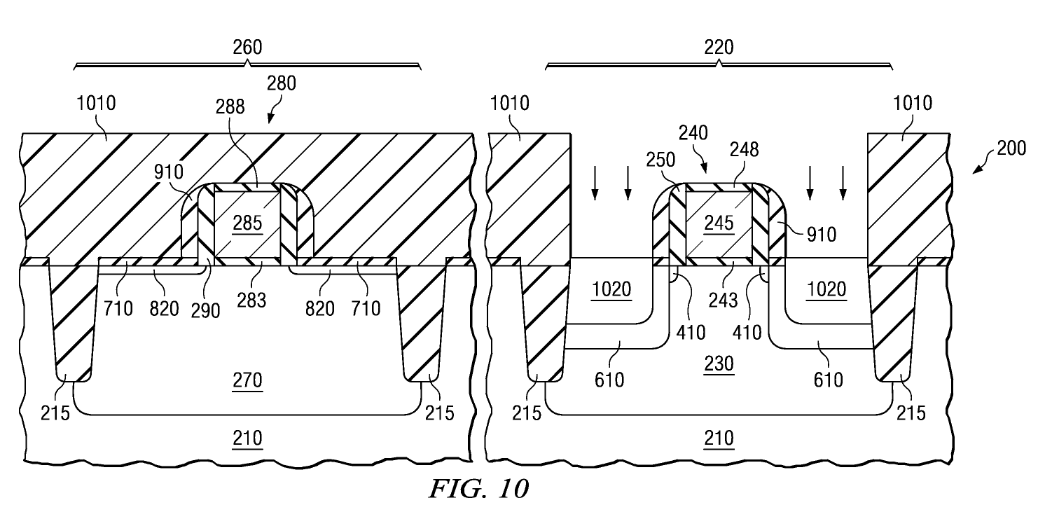

It is also within the scope of the disclosure to etch the recesses 510 to any suitable depth. In the example application, the recesses 510 are etched to a depth between about 10 nm and about 60 nm. Additionally, the depth of the recesses 510 may be approximately the same depth as the subsequently formed source/drain implants 1020 (see FIG. 10). Moreover, as shown, the recess etch is “selective” to the masking layer 310 as well as the gate hardmask 248. Therefore, the masking layer 310 protects the NMOS device region 260 from the recess etch and the gate hardmask 248 protects the gate electrode 245 in the PMOS device region 220 from the recess etch.

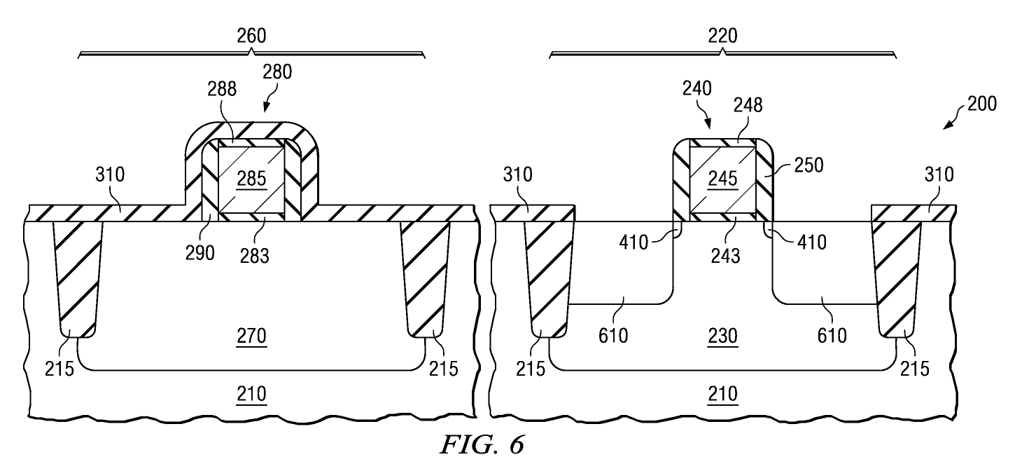

FIG. 6 illustrates the device 200 of FIG. 5 after forming silicon germanium within the recesses 510 to form recessed epitaxial silicon germanium (SiGe) regions 610. In one embodiment, the SiGe regions 610 are considered selective recessed SiGe regions because the silicon germanium is selectively deposited on the active silicon substrate 210 but not on any amorphous regions, such as the regions containing SiO₂ or Si₃N₄. In addition, the SiGe regions 610 may be doped or undoped. In the example application, the SiGe regions 610 are doped with a P-type dopant, for example boron.

It is within the scope of the embodiment to use any suitable process to form the SiGe regions 610. For example, reduced-temperature chemical vapor deposition (“RTCVD”), ultra-high vacuum chemical vapor deposition (“UHCVD”), molecular beam epitaxy (“MBE”), or a small or large batch furnace-based process may be used. In the example application, a RTCVD process is used to form the SiGe regions 610. The example RTCVD process uses a temperature range of about 450° C. to about 800° C. and a pressure between about 1 Torr and about 100 Torr. In addition, the RTCVD uses the silicon-bearing precursor DCS (dichlorosilane), the germanium-bearing precursor GeH₄ (germane), and the p-doping precursor B₂H₆ (diborane) Process selectivity is achieved by including HCl (hydrochloric acid) and the carrier gas H₂ (hydrogen).

While not shown in FIG. 6, the epi process may cause the SiGe regions 610 to extend above the top surface of the substrate 210. For example, the epi process not only back-fills the recesses 510, it also continues to grow to a height somewhere above the surface of the substrate 210. Forming the SiGe regions 610 thicker than the recesses 510 can mitigate damage thereto during subsequent removal processes.

As is illustrated in FIG. 6, the masking layer 310 protects the NMOS device region 260 and the gate hardmask 248 protects the gate electrode 245 in the PMOS device region 220 from the formation of the SiGe regions 610. It is to be noted that a resist layer should generally not be used in place of the masking layer 310 and the gate hardmask 248 because resist cannot typically withstand the high temperatures that are used for the formation of the SiGe regions 610. In addition, resist is comprised of organic material that could contaminate the machinery used in the epi process.

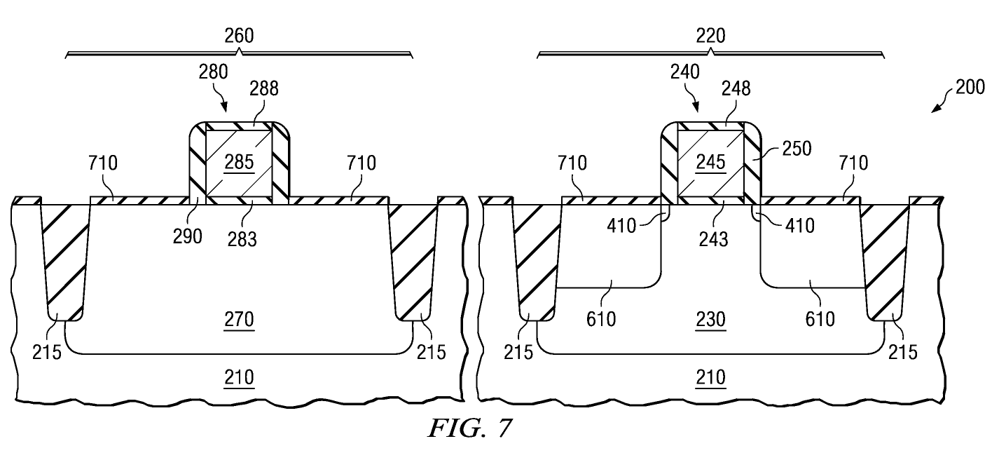

FIG. 7 illustrates the device 200 of FIG. 6 after removing the masking layer 310 and then forming raised portions 710 above the substrate 210 in at least the NMOS device region 260. Those skilled in the art understand the myriad of processes that might be used to remove the masking layer 310. For instance, many different processes might be used based on the type of material that the masking layer 310 comprises. In the example embodiment wherein the masking layer 310 comprises a first oxide material and a second nitride material, the second nitride material might be removed using a wet etch (e.g., a phosphoric acid strip) and the first oxide material might be removed using a HF wet etch. If the masking layer 310 were to comprise a different material or materials, another suitable etch would be used.

The raised portions 710, at least in the embodiment of FIG. 7, are located above the substrate 210 in the NMOS device region 260. Moreover, in the example embodiment of FIG. 7, the raised portions 710 are additionally located above the substrate 210 in the PMOS device region 220, and in this embodiment on the SiGe regions 610. In both embodiments, the raised portions 710 are located on opposing sides of the gate structure 280 and gate structure 240, respectively. Additionally, the raised portions 710 may have a thickness ranging from about 2 nm to about 40 nm, among others.

The raised portions 710, in one embodiment, are formed by growing undoped epitaxial silicon. The example RTCVD process uses a temperature range of about 650° C. to about 725° C. and a pressure between about 10 Torr and about 20 Torr. In addition, the RTCVD uses the silicon-bearing precursor DCS (dichlorosilane). Process selectivity is achieved by including HCl (hydrochloric acid) and the carrier gas H₂ (hydrogen). Accordingly, the undoped epitaxial silicon, at least in this embodiment, is selectively deposited. For example, the gate hardmasks 248, 288 required during the formation of the SiGe regions 610 help protect the gate electrodes 245, 285 from this selective deposition. Accordingly, few new steps are required to incorporate the raised portions 710 into the already existing process flow. This, in turn, allows the use of the raised portions 710 with little additional expense.+

In an alternative embodiment, the raised portions 710 comprise carbon substitutionally incorporated within silicon, or what is hereafter referred to as silicon carbon. In the embodiment wherein the raised portions 710 comprise silicon carbon, a process using a temperature ranging from about 450° C. to about 750° C. and a pressure ranging from about 1 Torr to about 100 Torr, might be used. In addition, the process might use the silicon-bearing precursor Si₃H₈ (trisilane), the carbon-bearing precursor SiCH₆ (methyl-silane), and the n-doping precursor PH₃ (phosphine). Process selectivity may be achieved by including HCl (hydrochloric acid) and the carrier gas H₂ (hydrogen)

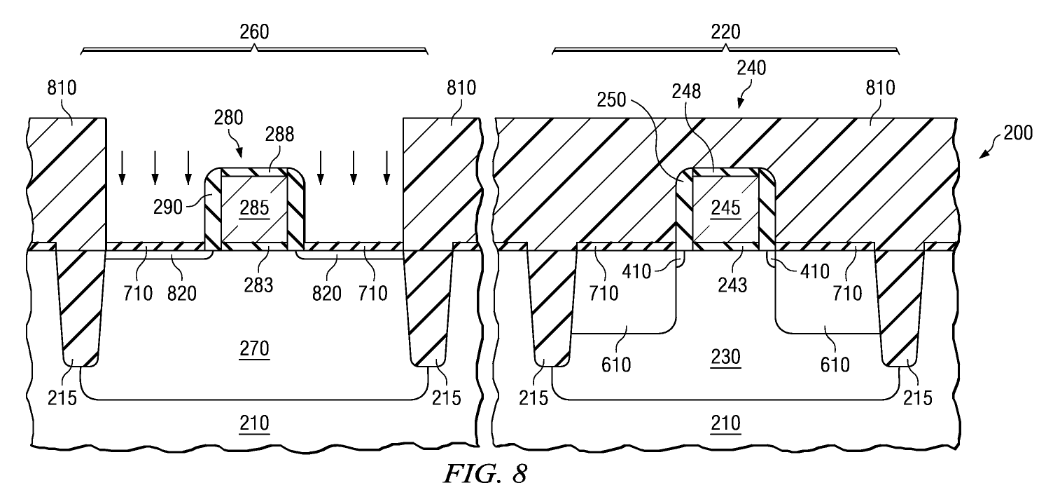

FIG. 8 illustrates the device 200 of FIG. 7 after patterning a resist layer 810 over the substrate 210 to expose at least a portion of the NMOS device region 260, and then forming second extension implants 820 within the substrate 210. The patterned resist layer 810, in the example embodiment, exposes the NMOS device region 260 while protecting the PMOS device region 220. The patterned resist layer 810 may be similar in material and manufacture to the previously described patterned resist layer 320.

The patterned resist layer 810, as well as the gate structure 280 in this embodiment, may then be used to position the second extension implants 820. In the illustrative embodiment, the extension implants 820 are located in at least a portion of the raised portions 710. Moreover, in the illustrative embodiment the extension implants 820 extend through the raised portions 710 and into a well region 270 located in the substrate 210.

The extension implants 820 may be conventionally formed and generally have a peak dopant concentration ranging from about 1E19 atoms/cm³ to about 2E20 atoms/cm³. As is standard in the industry, the implants 820 should have a dopant type opposite to that of the well region 270 they are located within. Accordingly, the implants 820 are doped with an N-type dopant.

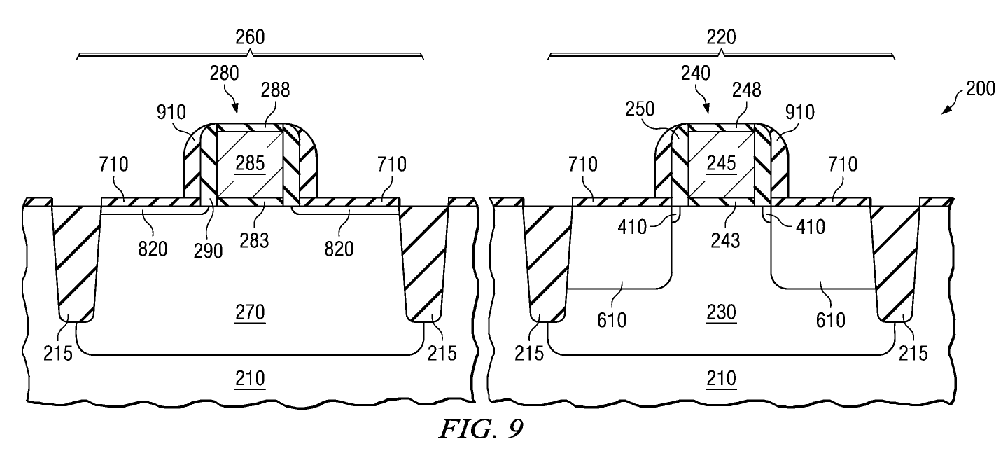

FIG. 9 illustrates the device 200 of FIG. 8 after removal of the patterned resist layer 810 and subsequent formation of source/drain sidewall spacers 910. Conventional processes may be used to remove the patterned resist layer 810. For example, a process similar to that used to remove the patterned resist layer 320 may be used to remove the patterned resist layer 810.

The source/drain sidewall spacers 910, as illustrated, may be located on opposing sides of the gate structure 240 and the gate structure 280. For example, as shown, the source/drain sidewall spacers 910 may be located directly on the gate sidewall spacers 290. Other configurations, however, could be used.

The source/drain sidewall spacers 910 may be formed using many different processes. In one embodiment, however, the source/drain sidewall spacers 910 comprise a nitride and are formed using a chemical vapor deposition (CVD) process. For example, a conformal layer of nitride may be formed over the entire substrate 210. Thereafter, the conformal layer of nitride may be subjected to an anisotropic etch, in this embodiment resulting in the source/drain sidewall spacers 910. Other embodiments exist wherein the source/drain sidewalls spacers 910 comprise a different material and are formed using a different suitable process.

FIG. 10 illustrates the device 200 of FIG. 9 after patterning a resist layer 1010 to expose the PMOS device region 220, and thereafter forming first source/drain implants 1020 in the substrate 210. The patterned resist layer 1010, in the example embodiment, exposes the PMOS device region 220 while protecting the NMOS device region 260. The patterned resist layer 1010 may be similar in material and manufacture to the previously described patterned resist layers 320, 810.

The patterned resist layer 1010, as well as the source/drain sidewall spacers 910 in this embodiment, may then be used to position the source/drain implants 1020. In the illustrative embodiment, the source/drain implants 1020 are located in at least a portion of the SiGe regions 610. Moreover, in the illustrative embodiment the source/drain implants 1020 extend through the raised portions 710 into the SiGe regions 610 in the PMOS device region 220.

The source/drain implants 1020 may be conventionally formed. Generally, the source/drain implants 1020 have a peak dopant concentration ranging from about 1E18 atoms/cm³ to about 1E21 atoms/cm³. Also, the source/drain implants 1020 typically have a dopant type opposite to that of the well region 230 they are located within. Accordingly, in the embodiment shown in FIG. 10, the source/drain implants 1020 are doped with a P-type dopant.

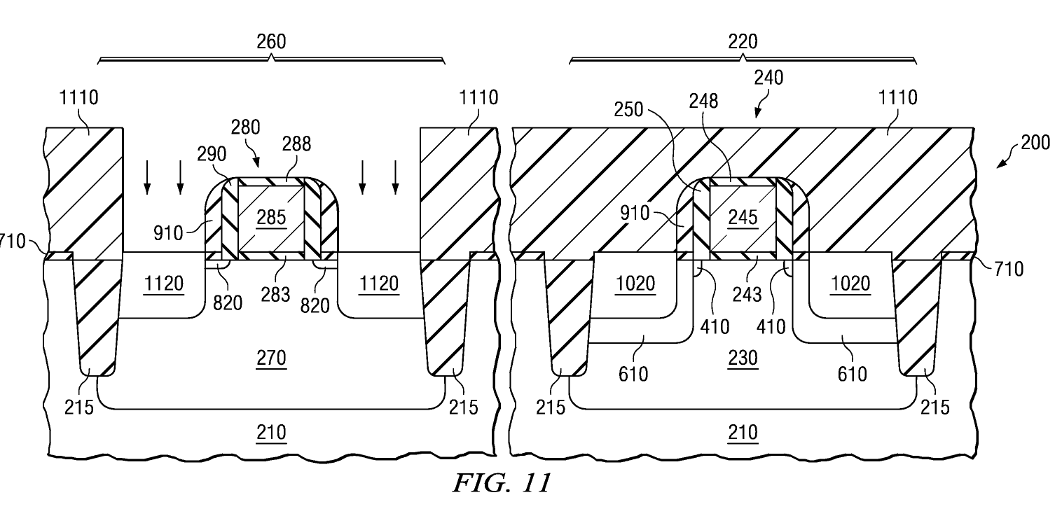

FIG. 11 illustrates the device 200 of FIG. 10 after removing the patterned resist layer 1010, patterning a resist layer 1110 to expose the NMOS device region 260, and thereafter forming second source/drain implants 1120 in the substrate 210. The patterned resist layer 1110, in the example embodiment, exposes the NMOS device region 260 while protecting the PMOS device region 220. The patterned resist layer 1110 may be similar in material and manufacture to the previously described patterned resist layers 320, 810, 1010.

The patterned resist layer 1110, as well as the gate structure 280 in this embodiment, may then be used to form the source/drain implants 1120. In the illustrative embodiment, the source/drain implants 1120 are located in at least a portion of the raised portions 710. Moreover, in the illustrative embodiment the source/drain implants 1120 extend through the raised portions 710 in the well region 270 in the substrate 210.

The source/drain implants 1120 may be conventionally formed. Generally, the source/drain implants 1120 have a peak dopant concentration ranging from about 1E18 atoms/cm³ to about 1E21 atoms/cm³. Also, the source/drain implants 1120 typically have a dopant type opposite to that of the well region 270 they are located within. Accordingly, in the embodiment shown in FIG. 11, the source/drain implants 1120 are doped with an N-type dopant.

After completing the device 200 of FIG. 11, conventional or not so conventional manufacturing processes could be used to complete the device 200. For example, the device 200 might be subjected to an anneal, thereby causing the extension implants 410, 820 and source/drain implants 1020, 1120, to form completed source/drain regions. As indicated in FIG. 1, the completed source/drain regions may comprise the extension implant 410, source/drain implant 1020 and raised portions 710 in the PMOS device region 220, and may comprise the extension implants 820, source/drain implants 1120, and raised portions 710 in the NMOS device region 260. Thus, the source/drain regions of the PMOS device region might include raised portions 710 and substrate portions (e.g., the SiGe regions 610) and the source/drain regions of the PMOS device region might include the raised portions 710 and substrate portions. Additionally, the device 200 of FIG. 11 may have the gate hardmasks 248, 288 removed from the gate structures 240, 280, respectively. Other manufacturing steps would likely also occur.

The process flow described with respect to FIGS. 2-11 illustrates but one embodiment of the disclosure. Other embodiments also exist. For instance, in another embodiment the SiGe regions 610 are formed after patterning of the gate structure 240, whether it is before or after the formation of the first extension implants 410. Accordingly, in another embodiment the first extension implants 410 are formed in the PMOS device region 220 after forming the SiGe regions 610. Likewise, in a different embodiment, the second extension implants 820 are formed prior to forming the raised portions 710.

In yet a different embodiment, the removal of the masking layer 310 and the formation of the raised portions 710 may be conducted in the same processing tool. For example, a single processing tool having multiple chambers could be used, wherein one chamber removes the masking layer 310 and another chamber forms the raised portions 710. In this embodiment, one would not need to break vacuum to form the various layers. In an even different embodiment, the deposition chamber used to form the raised portions 710 could be plumbed to include an etchant that might be used to remove the masking layer 310. In this embodiment, a single processing tool having only a single chamber might be used to accomplish both tasks. Other modifications and embodiments additionally exist.

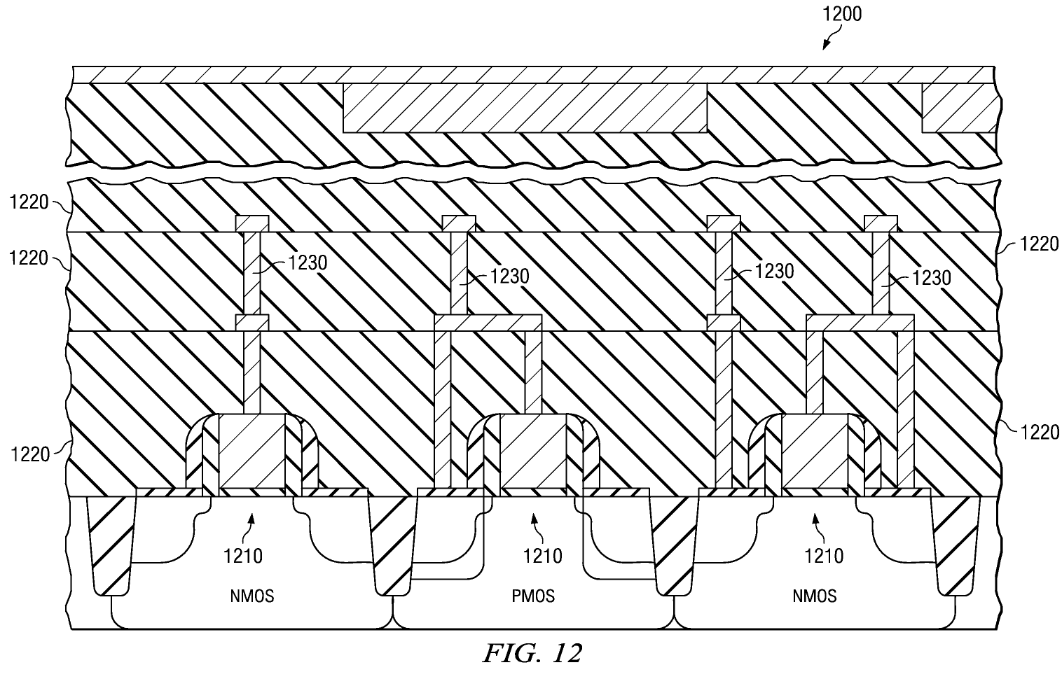

FIG. 12 illustrates an integrated circuit (IC) 1200 having been manufactured using one embodiment of the disclosure. The IC 1200 may include devices, such as transistors used to form CMOS devices, BiCMOS devices, Bipolar devices, as well as capacitors or other types of devices. The IC 1200 may further include passive devices, such as inductors or resistors, or it may also include optical devices or optoelectronic devices. Those skilled in the art are familiar with these various types of devices and their manufacture. In the particular embodiment illustrated in FIG. 12, the IC 1200 includes devices 1210, which in this embodiment are NMOS devices and PMOS devices. For instance, in one embodiment the NMOS devices and PMOS devices illustrated in FIG. 12 are manufactured using similar processes as described above with respect to FIGS. 2-11. Located over the devices 1210 are interlevel dielectric layers 1220. Located within the interlevel dielectric layers 1220 and contacting the devices 1210 are interconnects 1230. The resulting IC 1200 is optimally configured as an operational integrated circuit.

The phrase “providing a substrate”, as used herein, means that the substrate may be obtained from a party having already manufactured it, or alternatively may mean manufacturing the substrate themselves and providing it for its intended purpose.

Those skilled in the art to which the disclosure relates will appreciate that other and further additions, deletions, substitutions and modifications may be made to the described embodiments without departing from the scope of the disclosure.

What is claimed is:

1. A method for manufacturing a semiconductor device, comprising:
providing a substrate having a P-type metal oxide semiconductor (PMOS) device region and N-type metal oxide semiconductor (NMOS) device region;
forming a first gate structure including a first hardmask over the substrate in the PMOS device region and a second gate structure including a second hardmask over the substrate in the NMOS device region;
creating recessed epitaxial silicon germanium regions in the substrate on opposing sides of the first gate structure, the first hardmask protecting the first gate structure from the creating; and
forming first source/drain regions on opposing sides of the first gate structure, wherein at least a portion of each of the first source/drain regions is located within one of the recessed epitaxial silicon germanium regions; and
growing a raised portion above the substrate on opposing sides of the second gate structure, the raised portion forming at least a part of second source/drain regions located on opposing sides of the second gate structure, and further wherein the first and second hardmasks protect the first and second gate structures from the growing.

2. The method of claim 1 wherein forming recessed epitaxial silicon germanium regions includes forming a masking layer protecting the NMOS device region and exposing at least a portion of the PMOS device region, subjecting exposed portions of the PMOS device region to an etch to form recesses, and growing epitaxial silicon germanium within the recesses.

3. The method of claim 2 wherein the masking layer comprises silicon dioxide, silicon nitride, silicon carbide, silicon oxynitride or a combination thereof.

4. The method of claim 1 wherein growing the raised portions includes growing additional raised portions on the recessed epitaxial silicon germanium regions.

5. The method of claim 4 wherein the raised portions and the additional raised portions comprise a same material.

6. The method of claim 1 wherein growing the raised portions includes growing undoped epitaxial silicon.

7. The method of claim 1 wherein the second source/drain regions include extension implants and source/drain implants, and further wherein at least a portion of the source/drain implants are located in the raised portions above the substrate.

8. The method of claim 7 wherein at least a portion of the extension implants are located in the raised portions above the substrate.

9. The method of claim 1 further including forming interlevel dielectric layers over the first gate structure and the second gate structure, wherein the interlevel dielectric layers include interconnects therein for contacting the first gate structure and the second gate structure.

10. A method for manufacturing a semiconductor device, comprising:
providing a substrate having a P-type metal oxide semiconductor (PMOS) device region and N-type metal oxide semiconductor (NMOS) device region;
forming a first gate structure over the substrate in the PMOS device region and a second gate structure over the substrate in the NMOS device region;
forming recessed epitaxial silicon germanium regions in the substrate on opposing sides of the first gate structure; and
forming first source/drain regions on opposing sides of the first gate structure, wherein at least a portion of each of the first source/drain regions is located within one of the recessed epitaxial silicon germanium regions; and
forming second source/drain regions on opposing sides of the second gate structure, wherein each of the second source/drain regions includes a raised portion located above the substrate and does not comprise epitaxial silicon germanium.

11. A semiconductor device, comprising:
a P-type metal oxide semiconductor (PMOS) device region located over a substrate, including:
a first gate structure located over the substrate;
recessed epitaxial silicon germanium regions located in the substrate on opposing sides of the first gate structure; and
first source/drain regions located on opposing sides of the first gate structure, wherein at least a portion of each of the first source/drain regions is located within one of the recessed epitaxial silicon germanium regions; and
an N-type metal oxide semiconductor (NMOS) device region located over the substrate, including:
a second gate structure located over the substrate, the second gate structure including a second gate dielectric and a second gate electrode; and
second source/drain regions located on opposing sides of the second gate structure, wherein each of the second source/drain regions includes a raised portion located above the substrate and does not comprise epitaxial silicon germanium.

12. The semiconductor device of claim 11 wherein each of the second source/drain regions further includes a substrate portion located in the substrate.

13. The semiconductor device of claim 11 wherein the raised portions comprise epitaxial silicon.

14. The semiconductor device of claim 11 wherein the raised portions comprise silicon carbon.

15. The semiconductor device of claim 11 wherein the raised portions comprise a material, and further wherein each of the first source/drain regions includes an additional raised portion located above the substrate and comprising the same material.

16. The semiconductor device of claim 15 wherein the additional raised portions are located on the recessed epitaxial silicon germanium regions.

17. The semiconductor device of claim 11 wherein the second source/drain regions include extension implants and source/drain implants, and further wherein at least a portion of the source/drain implants are located in the raised portions above the substrate.

18. The semiconductor device of claim 17 wherein at least a portion of the extension implants are located in the raised portions above the substrate.

19. The semiconductor device of claim 11 further including interlevel dielectric layers located over the first gate structure and the second gate structure, wherein the interlevel dielectric layers include interconnects therein for contacting the first gate structure and the second gate structure.
